(19) United States
(12) Patent Application Publication
(10) Pub. No.: US 2009/0032913 A1
(43) Pub. Date: Feb. 5, 2009

(54) Component and assemblies with ends offset downwardly

(75) Inventor: Belgacem Haba, Cupertino, CA (US)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 12/284,686

(22) Filed: Sep. 24, 2008

Related U.S. Application Data
(62) Division of application No. 10/789,318, filed on Feb. 27, 2004.
(60) Provisional application No. 60/450,577, filed on Feb. 27, 2003.

(51) Int. Cl. H01L 23/552

(52) U.S. Cl. 257/659; 257/E23.114

(57) ABSTRACT

A stackable microelectronic component includes a dielectric layer having an attachment portion. The dielectric layer has a first side, a second side, and outer ends lying outwardly of the attachment portion. The outer ends are offset from the attachment portion. A semiconductor chip is assembled to the second side of the dielectric layer at the attachment portion. First terminal structures are carried by the outer ends of the dielectric layer for connecting the semiconductor chip with external circuitry located above the first side of the dielectric layer. Second terminal structures are carried by the outer ends of the dielectric layer for connecting the semiconductor chip with external circuitry located below the second side of the dielectric layer.

### CROSS-REFERENCE TO RELATED APPLICATIONS

This application is a divisional of U.S. application Ser. No. 10/789,318, filed Feb. 27, 2004, which claims the benefit of U.S. Provisional Application No. 60/450,577, filed Feb. 27, 2003, the disclosures of which are hereby incorporated by reference herein.

### BACKGROUND OF THE INVENTION

The present invention relates to microelectronic components, microelectronic assemblies and microelectronic packages, including assemblies having multiple microelectronic elements.

Semiconductor chips typically are formed as relatively thin, flat rectangular elements having front and rear surfaces and contacts on the front surface. The chips typically are provided in external elements or “packages” which mechanically protect the chip itself, and which also facilitate mounting of the chip to a substrate such as a circuit board or other circuit panel and making the required connections between the contacts of the chip and the circuit panel. Typically, the packages are arranged for mounting of the chip with the planes of the front and rear surfaces of the chip itself extending in horizontal directions, generally parallel to the plane of the underlying substrate. The horizontal dimensions of the package preferably are as small as possible so that the package occupies only a relatively small area of the circuit panel. This helps to make the overall assembly more compact and also reduces the length of signal lines connecting the circuit panel. It is also desirable to limit the height or thickness of the chip package, i.e., the vertical dimensions of the package.

One approach which has been suggested is to provide a small circuit panel, sometimes referred to as a “package substrate,” having top and bottom sides. A bottom-side chip is mounted to the bottom side of the package substrate. The package substrate bears terminals exposed at the bottom side of the substrate. These terminals are provided with conductive elements such as solder balls, projecting downwardly from the bottom side of the substrate. When the assembly is mounted on a circuit panel, the solder balls are bonded to contact pads of the circuit panel. In the assembled condition, the bottom-side chip lies between the package substrate and the circuit panel. A second or top-side chip may be mounted on the top surface of the package substrate. Examples of this approach are shown in U.S. Pat. Nos. 5,801,072 and 5,239,198. Because the solder balls must extend downwardly beyond the bottom chip, they must be disposed outside of the area occupied by the bottom-side chip. Also, the solder balls must be of substantial diameter, so that they project vertically beyond the bottom-side chip. Therefore, the solder balls and the corresponding contact pads on the substrate must be spaced apart at substantial horizontal distances. This tends to increase the area of the circuit panel occupied by the package.

It would be desirable to provide a package which incorporates the advantages associated with the above-mentioned package, but which minimizes the disadvantages noted above.

### SUMMARY OF THE INVENTION

In one aspect of the present invention, a stackable microelectronic component comprises a dielectric layer having an attachment portion and at least one offset portion offset from the attachment portion in a generally downward direction. The assembly has a semiconductor chip assembled to the attachment portion and terminal structures. First and second terminal structures are carried by the offset portion of the dielectric layer for connecting the semiconductor chip with external circuitry lying above and/or below the attachment portion. In certain embodiments, the offset portion is a portion of the dielectric layer that is folded over. In other embodiments, the offset portion comprises a bent portion of the dielectric layer. The terminal structure may include a via and/or bonding material, or any other structure for forming electrical connections.

The attachment portion of the dielectric layer is desirably planar. The dielectric layer, in certain preferred embodiments, has at least one bend between the attachment portion and the offset portion. The at least one bend may include a first bend in a first direction and a second bend in a second direction opposite to the first direction. The dielectric layer desirably has at least one conductor extending in bend. The at least one conductor may be arranged so as to support the bend in the dielectric layer. In certain preferred embodiments, the dielectric layer comprises a polymeric material molded so as to form the offset portion. The dielectric layer with the offset portion may be formed using numerous methods known in the art of forming polymeric articles, including molding, folding, pressing and other methods.

In certain embodiments of the invention the semiconductor chip is attached to the dielectric layer at the bottom surface of the dielectric layer and the offset portion of the dielectric layer extends generally downwardly alongside the semiconductor chip. In other embodiments, the semiconductor chip is attached to a top surface of the dielectric layer.

In certain embodiments, the offset portion of the dielectric layer comprises a portion that lies underneath the attachment portion of the dielectric layer. In other embodiments, the offset portion of the dielectric layer lies outwardly of the attachment portion. The dielectric layer may have at least one outer end and the terminal structures may be disposed at the at least one outer end. The at least one outer end may extend generally horizontally.

The semiconductor chip may comprise a first microelectronic element and the assembly may further comprise a second microelectronic element. In certain preferred embodiments, the first microelectronic element is disposed at a top surface of the dielectric layer and the second microelectronic element is disposed at a bottom surface of the dielectric layer. In certain embodiments, the assembly has a first dielectric layer and a second dielectric layer. A first microelectronic element may be attached to the first dielectric layer and the second microelectronic element may be attached to the second dielectric layer and arranged so that the second microelectronic element overlies the first microelectronic element.

A circuit element is desirably connected to the terminal structure so that the circuit element is disposed underneath the dielectric layer. In certain embodiments, the circuit element underlies the dielectric layer. The terminal structures desirably interconnect the semiconductor chip with the circuit element.

In certain embodiments, the dielectric layer includes traces connected to the terminal structures and connected to contacts of the semiconductor chip. The semiconductor chip desirably has a first face with contacts exposed at the first face. In certain preferred embodiments, the semiconductor chip is assembled to the attachment portion so that the first face faces in an upward direction. In other preferred embodiments, the first face faces in a downward direction. The first face may face toward or away from the dielectric layer.

In certain embodiments, the dielectric layer comprises a continuous sheet. The terminal structures may be connected to conductors extending through the attachment portion. The terminal structures may comprise bonding material. The terminal structures, in certain embodiments, comprise solder balls.

In a further aspect of the present invention, a stackable microelectronic component comprises a dielectric layer having an attachment portion and outer ends lying outwardly of the attachment portion. The outer ends are offset from the attachment portion. The assembly has a semiconductor chip assembled to the attachment portion and has first and second terminal structures carried by the outer ends of the dielectric layer for connecting the semiconductor chip with external circuitry.

In certain embodiments, the attachment portion of the dielectric layer is generally planar. The outer ends, in certain embodiments, extend downwardly alongside the semiconductor chip and have at least one conductor arranged so as to shield the semiconductor chip. In certain preferred embodiments, the dielectric layer has at least one bend in the dielectric layer between the attachment portion and the outer ends. The at least one bend may comprise a first bend in a first direction and a second bend in a second direction opposite to the first direction. The dielectric layer may have at least one conductor extending in the bend. The at least one conductor may be arranged so as to support the bend in the dielectric layer.

In certain preferred embodiments, the semiconductor chip is attached to the dielectric layer at a bottom surface of the dielectric layer and the outer ends of the dielectric layer extend generally downwardly alongside the semiconductor chip. In other embodiments, the semiconductor chip is attached to a top surface of the dielectric layer. The outer ends of the dielectric layer may extend generally horizontally. The outer ends may lie underneath the attachment portion of the dielectric layer. In other embodiments, the outer ends lie outwardly of the attachment portion.

In certain preferred embodiments, the semiconductor chip comprises a first microelectronic element and the assembly has a second microelectronic element. The first microelectronic element is disposed at a top surface of the dielectric layer and the second microelectronic element is disposed at a bottom surface of the dielectric layer. The assembly may include a first dielectric layer and a second dielectric layer so that the second microelectronic element is attached to the second dielectric layer and arranged so that the second microelectronic element overlies the first microelectronic element. The first microelectronic element is attached to the first dielectric layer.

A circuit element is desirably connected to the terminal structures so that the circuit element is disposed underneath the dielectric layer. In other embodiments, the circuit element overlies the dielectric layer. The terminal structures desirably interconnect the semiconductor chip with the circuit element.

In certain preferred embodiments, the dielectric layer includes traces connected to the terminal structures and connected to contacts of the semiconductor chip. The semiconductor chip desirably has a first face and contacts exposed at the first face. The semiconductor chip may be assembled with the attachment portion so that the first face faces in an upward direction. In other embodiments, the first face faces in a downward direction. The first face may face toward or away from the dielectric layer.

The dielectric layer desirably comprises a continuous sheet. The terminal structures are desirably connected to conductors extending through the attachment portion. The terminal structures may comprise bonding material. The terminal structures may comprise solder balls.

In a further aspect of the present invention, a microelectronic component comprises a dielectric layer comprising a continuous sheet having an attachment portion for assembly with a microelectronic element and an offset portion offset from the attachment portion. The component has terminal structures on the dielectric layer and conductors attached to the terminal structures. The terminal structures may include bonding material.

In certain embodiments, the dielectric layer includes at least one bend between the attachment portion and the offset portion. The at least one bend may comprise a first bend in a first direction and a second bend in a second direction opposite the first direction. The conductors may comprise a plurality of traces. At least one of the traces may be disposed in the bend. The attachment portion may be generally horizontal whereas the offset portion may generally extend downwardly.

In certain embodiments, the offset portion lies outwardly of the attachment portion. In other embodiments, the offset portion may lie underneath the attachment portion.

The terminal structures may include vias defined by the dielectric layer. The terminal structures may include bonding material. The terminal structures may also comprise solder balls.

### BRIEF DESCRIPTION OF THE DRAWINGS

These and other features, aspects, and advantages of the present invention will become better understood with regard to the following description, appended claims and accompanying drawings where:

FIG. 1 is a top right perspective view of an assembly in accordance with one embodiment of the invention;

FIG. 2 is a cross-sectional view of an assembly in accordance with the embodiment of FIG. 1;

FIG. 3 is a detailed view indicated on FIG. 2;

FIG. 4 is a detailed view of an assembly in accordance with a further embodiment of the invention;

FIG. 5 is a detailed view of an assembly in accordance with another embodiment of the invention;

FIG. 6 is a cross-sectional view of an assembly in accordance with the embodiment of FIGS. 1-3;

FIG. 7 is a cross-sectional view of an assembly in accordance with a further embodiment of the invention;

FIG. 8 is a cross-sectional view of an assembly in accordance with a further embodiment of the invention;

FIG. 9 is a cross-sectional view of an assembly in accordance with another embodiment of the invention;

FIG. 10 is a cross-sectional view of an assembly in accordance with a further embodiment of the invention;

FIG. 11 is a cross-sectional view of an assembly in accordance with yet another embodiment of the invention;

FIG. 12 is a cross-sectional view of an assembly in accordance with a further embodiment of the invention;

FIG. 13 is a cross-sectional view of an assembly in accordance with yet a further embodiment of the invention;

FIG. 14 is a cross-sectional view of an assembly in accordance with another embodiment of the invention; and

FIG. 15 is a top-right perspective view of another assembly in accordance with an embodiment of the invention;

FIG. 16 is a cross-sectional view of an assembly in accordance with another embodiment of the invention; and

FIG. 17 is a cross-sectional view of an assembly in accordance with a further embodiment of the invention.

### DETAILED DESCRIPTION

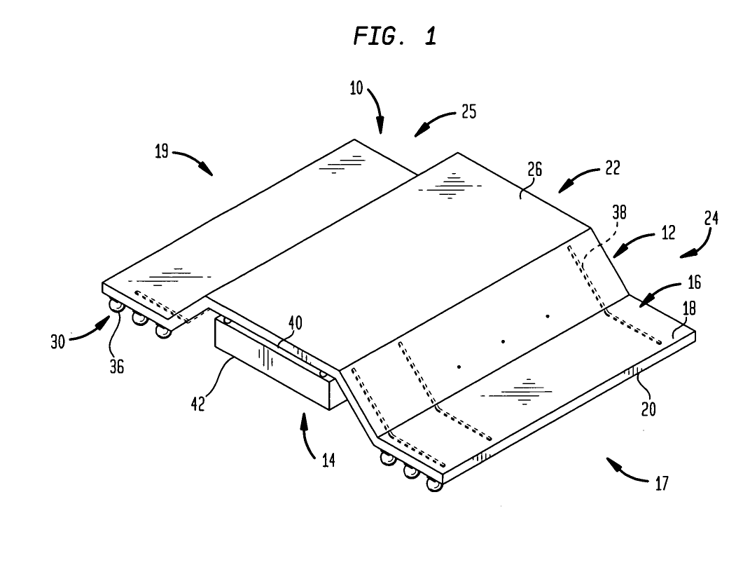

An embodiment of the present invention is illustrated in FIGS. 1-3 and 6. An assembly 10 comprises a component 12 and a microelectronic element comprising a semiconductor chip 14. The component 12 comprises a dielectric layer 16 having a top surface 18, a bottom surface 20 a first end 17, and a second end 19. References to “top,” “bottom,” “upper,” “lower,” “upwardly,” “downwardly,” and similar terms are not related to any gravitational frame of reference but to the particular part or assembly.

The dielectric layer has an attachment portion 22, a first offset portion 24 and a second offset portion 25 that lie at a lower lever than the attachment portion. In the embodiment shown, the attachment portion comprises a central portion 26 of the dielectric layer 16 and the offset portions 24 and 25 lie outwardly from the central portion 26. The offset portions 24 and 25 comprise the first end 17 and second end 19 of the dielectric layer 16. However, in other embodiments, the offset portions 24 and 25 may comprise one or more ends of the dielectric layer 16 or a peripheral portion of the dielectric layer 16 that surrounds the attachment portion 22 and lies outwardly of the attachment portion 22. In the embodiment depicted in FIGS. 1-3 and 6, the dielectric element, and particularly the attachment portion 22, are imperforate and hence do not have openings extending through the dielectric layer between the opposite surfaces of such layer.

The dielectric layer has terminal structures 30 in the offset portions 24 and 25. The terminal structures 30 comprise electrically conductive materials for forming connections with external circuitry and are connected to traces 38 (FIGS. 1 and 3) that extend from the offset portions to the attachment portion 22. The terminal structures 30 may comprise electrically conductive bonding material, such as solder balls 36. The traces 38 extend on or are disposed within the dielectric layer 16. Only a few traces are shown in FIG. 1 for clarity of illustration. The traces 38 have pads 32 that are connected to the terminal structures 30. The traces 38, pads 32, and terminal structures 30 may comprise electrically conductive features of copper, gold or other materials known in the art for making microelectronic components and devices. Such features may be formed using techniques known in the art, such as photolithography, etching, electroplating and other techniques. Also, the dielectric element may include more than one layer of conductive features, and may include features such as electrically conductive planes commonly used as ground planes or power distribution planes. The dielectric element, with the conductive features, desirably has sufficient physical strength to maintain its bent configuration. A reinforcing structure, such as a metallic heat shield (not shown) may be formed separately from the dielectric element and attached to the dielectric element to help maintain the bent configuration.

The traces 38 may extend on or at the top surface 18, bottom surface 20, or both, or may be disposed within the dielectric layer. The terminal structures 30 may includes vias extending through the dielectric layer and may have electrically conductive material lining the vias.

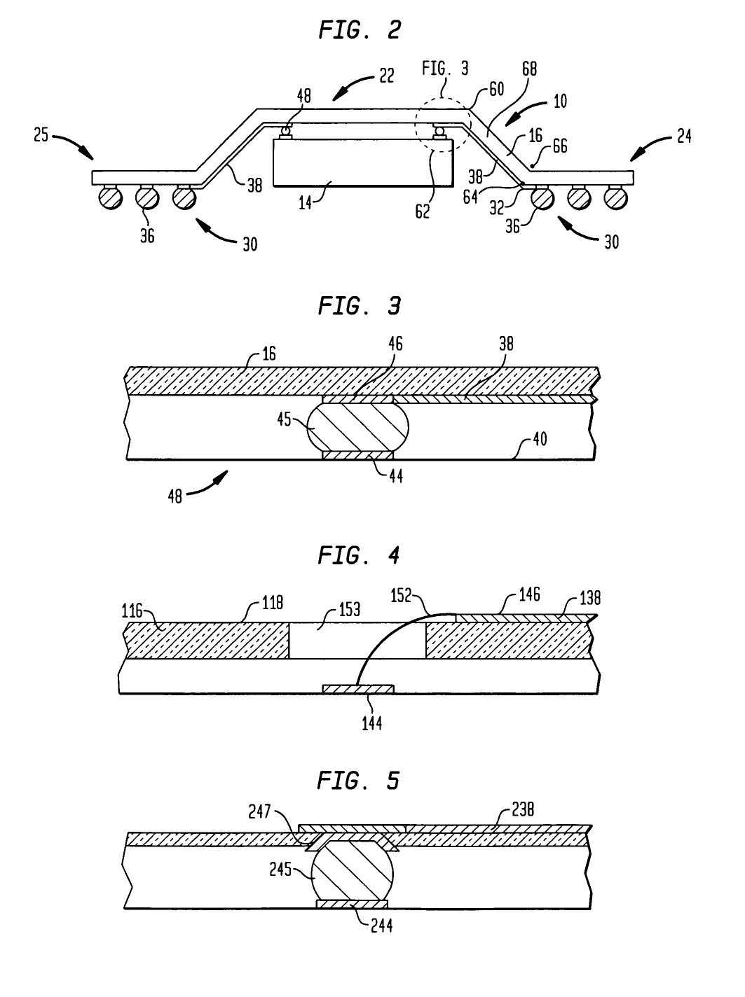

In the component 12 shown in FIG. 2, the dielectric layer 16 includes a first bend 60 around a first axis 62 and a second bend 64 around a second axis 66. The first bend 60 is disposed adjacent the attachment portion 22. The dielectric layer 16 has an arm 68 extending downwardly from the first bend 60 to the second bend 64 and offset portion 24. The first bend 60 comprises a bend around the first axis in a first direction and the second bend 64 comprises a bend around the second axis in a second direction that is opposite to the first direction. Similar bends are disposed between 22 and 25.

The microelectronic element 14 has a first face 40 and a second face 42 facing in an opposite direction from the first face 40. The microelectronic element 14 has contacts 44 exposed at the first face 40 and the microelectronic element 14 is arranged with the attachment portion 22 of the dielectric layer 16 so that the first face 40 faces the bottom surface 20 and is aligned with the attachment portion 22. The contacts 44 are aligned with bonding ends 46 of the traces 38 disposed in or adjacent to the attachment portion 22. The contacts 44 are connected to the bonding ends 46 (FIG. 3), and thereby connected to the terminal structures 30, using bonding material 45 disposed between the bonding ends 46 and the contacts 44. Flip-chip methods of bonding may be used. An underfill may be disposed between the microelectronic element 14 and the dielectric layer 16. FIG. 3 illustrates the connection 48 having bonding material 50 disposed between the contacts 44 and the bonding ends 46.

In other embodiments, the microelectronic element 14 is electrically connected to the component 12 using other methods. For example, as shown in FIG. 4, a flexible wire 152 may be connected at one end to a contact 144 and connected at another end to the bonding end 146. In this embodiment, the traces 138 may be disposed on the top surface 118 of the dielectric layer 116. Wire 152 extends through a hole 153 in the dielectric layer. The connection may also be formed by using electrically conductive adhesive between the bottom surface of the dielectric layer and the first face of the microelectronic element. In a further embodiment, leads (not shown) formed integrally with traces 138 may be bonded to contacts 144 through hole 153 as, for example, by sonic thermal or thermosonic bonding. Leads formed integrally with traces on the bottom surface of the dielectric layer, such as traces 38 (FIG. 4) may be bonded using a tool advanced through a hole in the dielectric layer. As shown in FIG. 5, the connection may be made by disposing bonding material 245 between a contact 244 and a via 247 connected to the traces 238.

The second face 42 of the chip 14 may be exposed. In other embodiments, the assembly is encapsulated. The second face 42 may be disposed at or near a surface of the package so as to be in thermal contact with a circuit element, circuit board, or other element. Although the drawings depict the second or downwardly-facing surface 42 of chip as recessed above the offset portions 24 and 25 of the dielectric element, this is not essential. The downwardly-facing surface of the chip may project slightly beyond the downwardly-facing surfaces of the offset portions, or may be coplanar therewith. However, the chip desirably does not project downwardly beyond the terminal structures 30. If the chip is encapsulated, the encapsulant desirably does not project downwardly beyond the terminal structures 30.

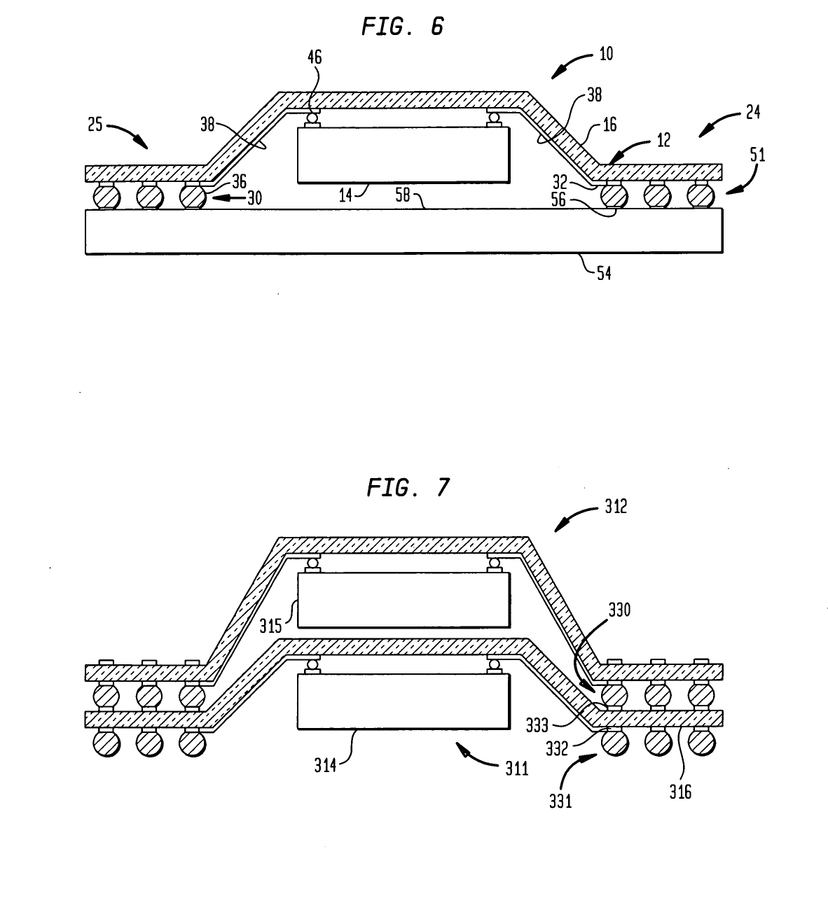

The assembly 10 is juxtaposed with a circuit element 54 such as a circuit board or other circuit panel (FIG. 6) having a plurality of terminals 56 exposed at a surface 58 of the circuit element 54. The assembly 10 is juxtaposed with the circuit element 54 so that the terminal structures 30 are aligned with the terminals 56. The terminal structures 30 are then connected to the terminals 56. In an embodiment in which the terminal structures 30 comprise solder balls 36, the solder balls are brought into contact with the terminals 56 and heated to thereby connect the terminals 56 with the pads 32 on the component 12. This procedure may be performed using conventional techniques commonly used in surface-mounting of electrical components. As the traces 38 connect the pads 32 to the contacts 44, the microelectronic element 14 is electrically connected to the circuit element 54. As shown in FIG. 6, the assembly 10 is disposed above the circuit element 54.

Because offset portions 24 and 25 are offset from the attachment portion 22 in a downward direction, the connection 51 between the component 12 and the circuit element 54 has a reduced dimension in height, as compared with a connection made using a component without such offset portions. In the case of the solder balls 36, the reduced dimension in height results in a reduced diameter solder ball, so that smaller solder balls can be used. The solder balls and the contacts pads 56 take up less area on the component 12. More solder balls can be included on a component occupying a given area of circuit element 54. Alternatively, the solder balls may have a greater spacing from adjacent solder balls without increasing the required area. Thin layers of solder, commonly referred to as “solder lands” can be used instead of solder balls.

In certain preferred embodiments, two or more assemblies may be connected to one another. As shown in FIG. 7, a first assembly 311 and a second assembly 312 are connected to one another in a stacked arrangement so that the terminal structures 330 of the second assembly 312 are connected to the first assembly 311. Each of the first assembly and second assembly have dielectric layers with a top surface and a bottom surface and traces, as discussed above in connection with assembly 10. Each dielectric layer has an attachment portion and a microelectronic element connected to pads. The first assembly 311 has traces with first pads 332 and second pads 333 disposed on opposite sides of the dielectric layer 316. The first pads are exposed at the top surface of the dielectric layer 116, and the second pads 133 are exposed at the top surface 118 of the dielectric layer 116. Although first pads 332 and second pads 333 are depicted as separate elements, these pads may be integral with one another. For example, a single pad may be formed on one surface of the dielectric and exposed at the opposite surface through a hole in the dielectric, so that the same pad functions as both a first pad and a second pad. The first assembly 311 has terminal structures 331 for forming connections with external circuitry. The traces of the dielectric layer 116 connect the terminal structures 331 with contacts of the first microelectronic element 314 and/or contacts of the second microelectronic element 315. Traces may also connect terminal structures 331 with terminal structures 330. The first assembly is juxtaposed with the second assembly so that the terminal structures 330 of the second assembly 312 are aligned with the second pads 333. As shown in FIG. 7, the assemblies each have a microelectronic element connected to an attachment portion of the dielectric layer of the assembly. The assemblies are stacked so that the second assembly overlies the first assembly and the second microelectronic element overlies the first microelectronic element. The stacked assemblies may be connected to terminals of an external circuit element by connecting the terminals structures 331 to terminals of the circuit element. A plurality of two or more assemblies may be stacked.

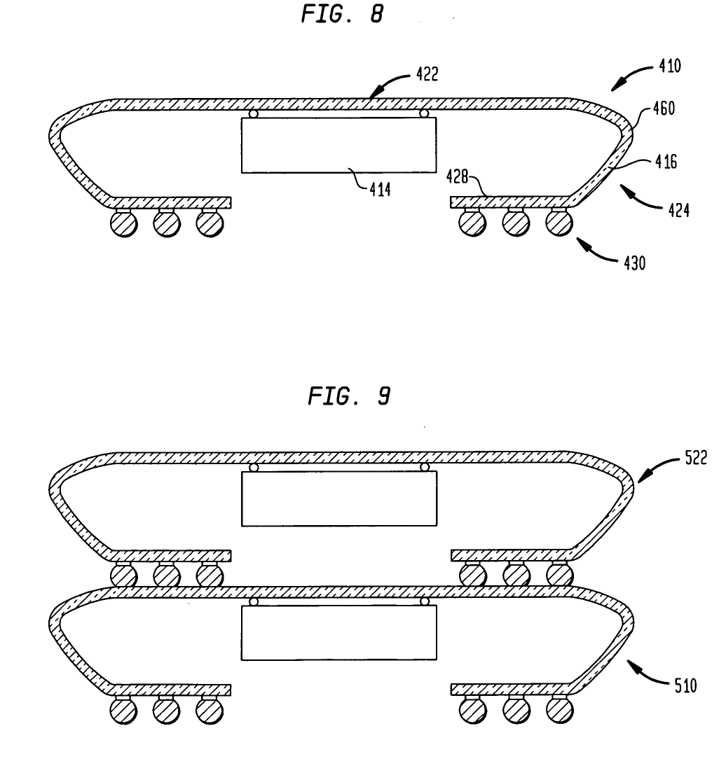

In a further embodiment, as shown in FIG. 8, the offset portion 424 comprises an end 428 of the dielectric layer 416 that is folded downwardly. The dielectric layer 416 extends from the attachment portion 422 around a bend 460 to the end 428 of the dielectric layer 416. As shown in FIG. 8, the offset portion 424 is disposed underneath the attachment portion 422. The offset portion 424 may be disposed outwardly of the microelectronic element 414, as shown in FIG. 8. Alternatively, the offset portion 424 may be disposed underneath the microelectronic element 414. The component 412 has terminal structures 430 in the offset portion 424 for connection with a circuit element. The assembly 410 may be connected to a circuit element. The assembly 410 may comprise a first assembly 510 and a second assembly 522 may be connected to the first assembly 510, as shown in FIG. 9, in a manner similar to that discussed above in connection with FIG. 7.

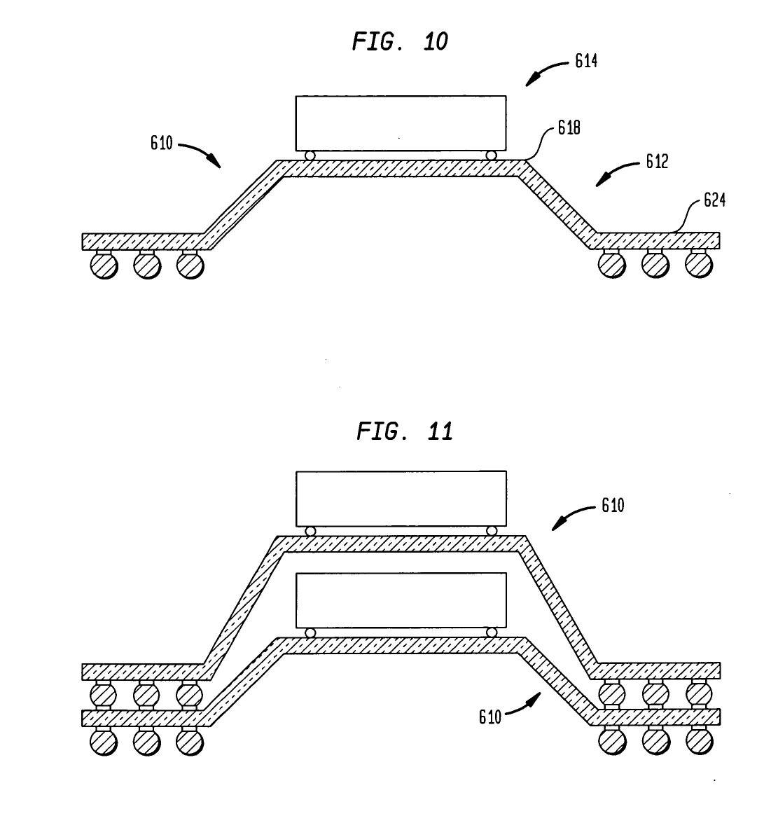

In further embodiments, as shown in FIG. 10, the microelectronic element 614 is connected to the top surface 618 of the dielectric layer 616 so that the microelectronic element 614 overlies the component 612. The assembly 610 has an offset portion 624 that is offset downwardly with respect to the attachment portion 622 of the dielectric layer 616. In addition, such assemblies 610 can be assembled with one another in a stacked arrangement, as shown in FIG. 11. A single assembly 610, or a stack of assemblies may be connected to an external circuit element.

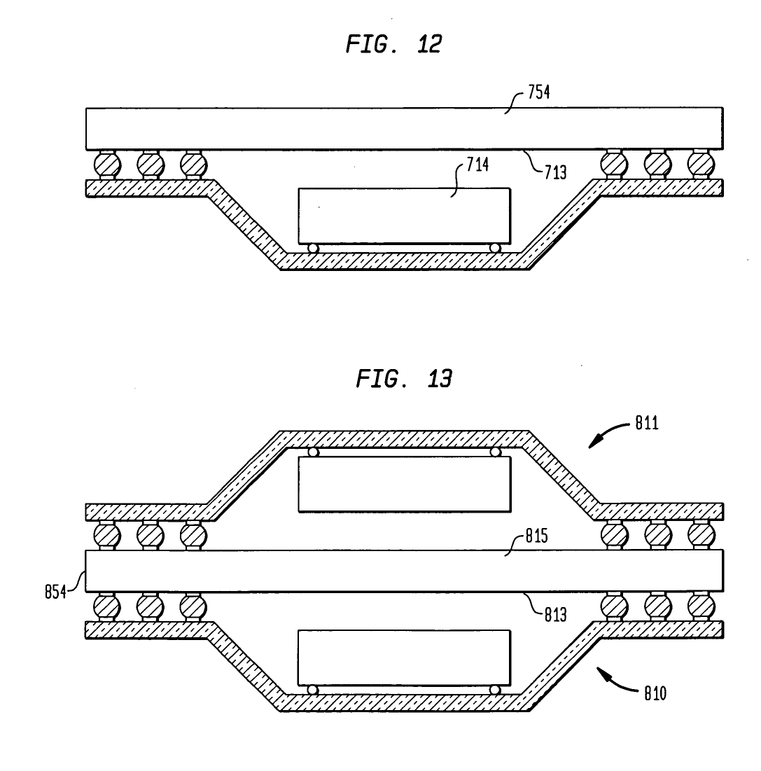

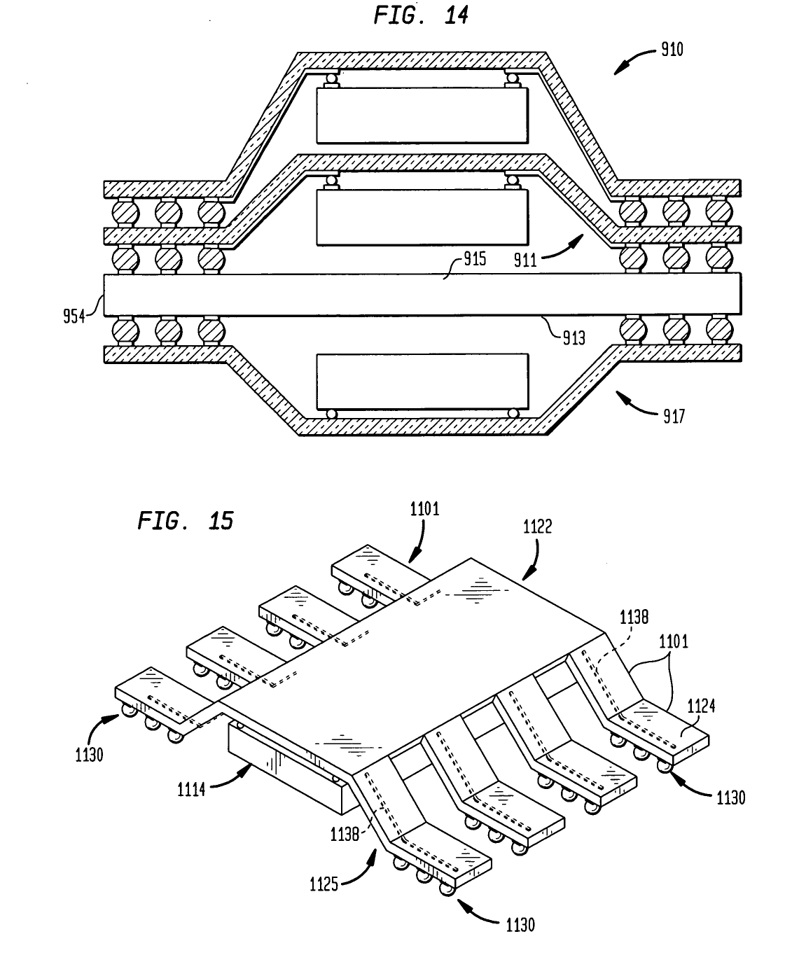

Components according to the present invention may be used in assembles that are connected to one or both sides of a circuit element. As shown in FIG. 12, an assembly may be connected to a lower side 713 of a circuit element 754 so that the microelectronic element 714 underlies the circuit element. In a further embodiment, as shown in FIG. 13, an assembly 810 is connected to the lower side 813 of the circuit element 854 and a second assembly 811 is connected to an upper side 815 of the circuit element 854. The microelectronic elements may be connected to the top surface or bottom surface of the dielectric layer to which the microelectronic element is attached. A stack of assemblies 910, 911 (FIG. 14) may be connected on either the upper side 915 or the lower side 913 of the external circuit element 954. As shown in FIG. 14, a stack of assemblies 910, 911 is connected at the upper side 915 and a further assembly 917 is connected at lower side 913.

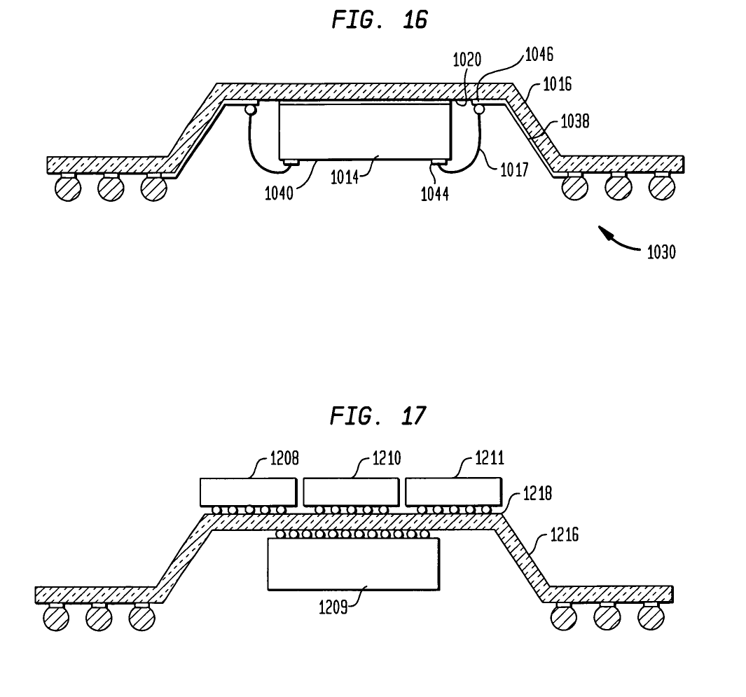

As shown in FIG. 16, the assembly may include a microelectronic element 1014 having a first face 1040 that faces away from the bottom surface 1020 of the dielectric layer 1016. The second-face 1042 is adhered to bottom surface 1020 of dielectric layer 1016. Contacts 1044 on the first face 1040 are connected to bonding ends 1046 on the bottom surface 1020 of the dielectric layer 1016 by flexible leads 1017. Wire bonding wires, as known in the art, may be attached at one end to the contacts 1044 and at another end to the bonding ends 1046. Traces 1038 of the dielectric layer connect the bonding ends 1046 to the terminal structures 1030 for the component. The first face 1040 may be disposed so as to be in thermal contact with a circuit element, circuit board, or other element.

In a further embodiment of the invention, as shown in FIG. 15, the component may comprise a dielectric layer having a plurality of fingers 1101. The fingers 1101 have offset portions 1124 and 1125 that are offset downwardly with respect to the attachment portion 1122. One or more fingers 1101 include the terminal structures 1130 and traces 1138 or similar conductive features on the component 1112. The traces are utilized to connect the terminal structures 1130 to the microelectronic element 1114.

In a further embodiment, more than one microelectronic element is arranged side by side on one or both sides of the dielectric element. As shown in FIG. 17, three microelectronic elements 1208, 1210 and 1211 are connected to the dielectric element 1216 in a side-by-side arrangement at the top surface 1218 of the dielectric layer 1216. One or more further microelectronic elements 1209 may be connected at the bottom surface 1220 of the dielectric layer 1216.

As used herein, “microelectronic element” includes a semiconductor chip, circuit board, substrate, component, passive element, assemblies of the foregoing such as stacked semiconductor chips or multi-chip modules. The microelectronic element may have contacts arranged in one or more rows at a peripheral area or central area of the element, distributed across the element, or in any other configuration. The term “semiconductor chip” as used herein refers to a chip which incorporates active circuit elements such as diodes, transistors, logic elements, memory elements and the like, and thus excludes structures which incorporate only passive elements such as conductors, resistors, capacitors and inductors.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention.

1. A stackable microelectronic component, comprising:
a) a dielectric layer having an attachment portion, a first side of the dielectric layer in the attachment portion facing in a first direction, an oppositely facing second side of the dielectric layer in the attachment portion facing in a second direction, the dielectric layer having at least one offset portion offset from the attachment portion such that the offset portion is skewed in the second direction in relation to said attachment portion;
b) a semiconductor chip assembled to the second side of the dielectric layer in the attachment portion;
c) first terminal structures disposed on the offset portion of the dielectric layer and connecting the semiconductor chip with external circuitry located above the first surface of the dielectric layer at the offset portion; and
d) second terminal structures disposed on the offset portion of the dielectric layer and connecting the semiconductor chip with external circuitry located below the second surface of the dielectric layer at the offset portion.

2. The stackable microelectronic component of claim 1, wherein the attachment portion of the dielectric layer is generally planar.

3. The stackable microelectronic component of claim 1, wherein the dielectric layer has at least one bend in the dielectric layer between the attachment portion and the offset portion.

4. The stackable microelectronic component of claim 3, wherein the at least one bend comprises a first bend in the first direction and a second bend in the second direction opposite to the first direction.

5. The stackable microelectronic component of claim 4, wherein the dielectric layer has at least one conductor extending in the bend.

6. The stackable microelectronic component of claim 5, wherein the at least one conductor is arranged so as to support the bend in the dielectric layer.

7. The stackable microelectronic component of claim 1, wherein the dielectric layer comprises a polymeric material molded so as to form the offset portion.

8. The stackable microelectronic component of claim 1, wherein the semiconductor chip is attached to the dielectric layer at a bottom surface of the dielectric layer and the offset portion of the dielectric layer extends generally downwardly alongside the semiconductor chip.

9. The stackable microelectronic component of claim 8, wherein the dielectric layer has at least one conductor, arranged so as to shield the semiconductor chip.

10. The stackable microelectronic component of claim 1, wherein the offset portion of the dielectric layer comprises a portion that lies underneath the attachment portion of the dielectric layer.

11. The stackable microelectronic component of claim 1, wherein the offset portion of the dielectric layer comprises a portion that lies outwardly of the attachment portion of the dielectric layer.

12. The stackable microelectronic component of claim 1, wherein the dielectric layer has at least one outer end and the terminal structures are disposed at the at least one outer end.

13. The stackable microelectronic component of claim 12, wherein the at least one outer end extends generally horizontally.

14. The stackable microelectronic component of claim 1, wherein the semiconductor chip comprises a first microelectronic element and a second microelectronic element, the first microelectronic element being disposed at the first surface of the dielectric layer, and the second microelectronic element being disposed at the second surface of the dielectric layer.

15. The stackable microelectronic component of claim 14, wherein the dielectric layer comprises a first dielectric layer and a second dielectric layer, the second microelectronic element being attached to the second dielectric layer and arranged so that the second microelectronic element overlies the first microelectronic element.

16. The stackable microelectronic component of claim 1, further comprising a circuit element connected to the second terminal structures so that the circuit element is disposed underneath the dielectric layer.

17. The stackable microelectronic component of claim 16, wherein the second terminal structures interconnect the semiconductor chip with the circuit element.

18. The stackable microelectronic component of claim 1, wherein the dielectric layer includes traces connected to one of the first and second terminal structures and connected to contacts of the semiconductor chip.

19. The stackable microelectronic component of claim 1, wherein the semiconductor chip has a first face with contacts exposed at the first face.

20. The stackable microelectronic component of claim 19, wherein the semiconductor chip is assembled to the attachment portion so that the first face faces in the first direction.

21. The stackable microelectronic component of claim 1, wherein the dielectric layer comprises a continuous sheet.

22. The stackable microelectronic component of claim 1, wherein one or more of the first and second terminal structures comprise bonding material.

23. The stackable microelectronic component of claim 1, wherein one or more of the first and second terminal structures are connected to conductors extending through the attachment portion.

24. The stackable microelectronic component of claim 1, wherein one or more of the first and second terminal structures comprise solder balls.

25. A stackable microelectronic component, comprising:
a) a dielectric layer having an attachment portion, the dielectric layer having a first side, a second side, and outer ends lying outwardly of the attachment portion, the outer ends being offset from the attachment portion;
b) a semiconductor chip assembled to the second side of the dielectric layer at the attachment portion;
c) first terminal structures carried by the outer ends of the dielectric layer for connecting the semiconductor chip with external circuitry located above the first side of the dielectric layer; and
d) second terminal structures carried by the outer ends of the dielectric layer for connecting the semiconductor chip with external circuitry located below the second side of the dielectric layer.

26. The stackable microelectronic component of claim 25 wherein the attachment portion of the dielectric layer is substantially planar.

27. The stackable microelectronic component of claim 25, wherein the outer ends extend downwardly alongside the semiconductor chip and have at least one conductor, arranged so as to shield the semiconductor chip.

28. The stackable microelectronic component of claim 25, wherein the dielectric layer has at least one bend in the dielectric layer between the attachment portion and the outer ends.

29. The stackable microelectronic component of claim 28, wherein the at least one bend comprises a first bend in a first direction and a second bend in a second direction opposite to the first direction.

30. The stackable microelectronic component of claim 28, wherein the dielectric layer has at least one conductor extending in the bend.

31. The stackable microelectronic component of claim 30, wherein the at least one conductor is arranged so as to support the bend in the dielectric layer.

32. The stackable microelectronic component of claim 25, wherein the outer ends of the dielectric layer extend substantially away from the first side of the attachment portion of the dielectric layer.

33. The stackable microelectronic component of claim 25, wherein the outer ends of the dielectric layer extend generally horizontally.

34. The stackable microelectronic component of claim 25, wherein the outer ends lie underneath the attachment portion of the dielectric layer.

35. The stackable microelectronic component of claim 25, wherein the outer ends lie outwardly of the attachment portion of the dielectric layer.

36. The stackable microelectronic component of claim 25, wherein the semiconductor chip comprises a first microelectronic element and further comprising a second microelectronic element, the first microelectronic element being disposed at a top surface of the dielectric layer and the second microelectronic element being disposed at a bottom surface of the dielectric layer.

37. The stackable microelectronic component of claim 36, wherein the dielectric layer comprises a first dielectric layer and further comprising a second dielectric layer, the second microelectronic element being attached to the second dielectric layer and arranged so that the second microelectronic element overlies the first microelectronic element.

38. The stackable microelectronic component of claim 25, further comprising a circuit element connected to the second terminal structures so that the circuit element is disposed underneath the dielectric layer.

39. The stackable microelectronic component of claim 38, wherein the second terminal structures interconnect the semiconductor. chip with the circuit element.

40. The stackable microelectronic component of claim 25, wherein the dielectric layer includes traces connected to one or more of the first and second terminal structures and connected to contacts of the semiconductor chip.

41. The stackable microelectronic component of claim 25, wherein the semiconductor chip has a first face and contacts exposed at the first face.

42. The stackable microelectronic component of claim 41, wherein the semiconductor chip is assembled to the attachment portion so that the first face faces in an upward direction.

43. The stackable microelectronic component of claim 25, wherein the dielectric layer comprises a continuous sheet.

44. The stackable microelectronic component of claim 25, wherein one or more of the first and second terminal structures comprise bonding material.

45. The stackable microelectronic component of claim 25, wherein one or more of the first and second terminal structures are connected to conductors extending through the attachment portion.

46. The stackable microelectronic component of claim 25, wherein one or more of the first and second terminal structures comprise solder balls.
